(19) United States
(12) Patent Application Publication
(10) Pub. No.: US 2015/0092488 A1
(43) Pub. Date: Apr. 2, 2015

(54) FLASH MEMORY SYSTEM ENDURANCE IMPROVEMENT USING TEMPERATURE BASED NAND SETTINGS

(71) Applicants: Yogesh Wakchaure, Folsom, CA (US); Kiran Pangal, Fremont, CA (US); Xin Guo, San Jose, CA (US)

(72) Inventors: Yogesh Wakchaure, Folsom, CA (US); Kiran Pangal, Fremont, CA (US); Xin Guo, San Jose, CA (US)

(21) Appl. No.: 14/040,239

(22) Filed: Sep. 27, 2013

(51) Int. Cl. G11C 16/34; G11C 16/10; G11C 16/26

(52) U.S. Cl. CPC G11C 16/349; G11C 16/26; G11C 16/10
USPC 365/185.03; 365/185.18

(57) ABSTRACT

Methods and apparatus to improve flash memory system endurance using temperature based flash memory settings are described. In one embodiment, memory controller logic applies one of a first trim profile or a second trim profile to a flash memory storage device based at least partially on a comparison of a threshold temperature value and a sensed temperature of the flash memory storage device. Other embodiments are also disclosed and claimed.

### FIELD

The present disclosure generally relates to the field of electronics. More particularly, some embodiments generally relate to improving flash memory system endurance using temperature based setting in a NAND flash memory.

### BACKGROUND

Generally, memory used to store data in a computing system can be volatile (to store volatile information) or non-volatile (to store persistent information). Volatile data structures stored in volatile memory are generally used for temporary or intermediate information that is required to support the functionality of a program during the run-time of the program. On the other hand, persistent data structures stored in non-volatile memory are available beyond the run-time of a program and can be reused. Moreover, new data is typically generated as volatile data first, before the user or programmer decides to make the data persistent. For example, programmers or users may cause mapping (i.e., instantiating) of volatile structures in volatile main memory that is directly accessible by a processor. Persistent data structures, on the other hand, are instantiated on non-volatile storage devices like rotating disks attached to Input/Output (I/O or IO) buses or non-volatile memory based devices like flash memory.

As processing capabilities are enhanced in processors, one concern is the speed at which memory may be accessed by a processor. For example, to process data, a processor may need to first fetch data from a memory. After completion of the data processing, the results may need to be stored in the memory. Therefore, the memory speed can have a direct effect on overall system performance.

Another important consideration is power consumption. For example, in mobile computing devices that rely on battery power, it is very important to reduce power consumption to allow for the device to operate while mobile. Power consumption is also important for non-mobile computing devices as excess power consumption may increase costs (e.g., due to additional power usage, increasing cooling requirements, etc.), shorten component life, limit locations at which a device may be used, etc.

Hard disk drives provide a relatively low-cost storage solution and are used in many computing devices to provide non-volatile storage. Disk drives however use a lot of power when compared to flash memory since a disk drive needs to spin its disks at a relatively high speed and move disk heads relative to the spinning disks to read/write data. This physical movement generates heat and increases power consumption. To this end, some higher end mobile devices are migrating towards flash memory devices that are non-volatile.

NAND memory is a type of flash memory that is non-volatile. NAND memory may be used in memory cards, flash drives, solid-state drives, and similar products. However, flash memory has a limitation on the number of times the information in a memory cell may be rewritten before the memory cell becomes unusable, also referred to as a finite number of program-erase cycles (also referred to as P/E cycles).

### BRIEF DESCRIPTION OF THE DRAWINGS

The detailed description is provided with reference to the accompanying figures. In the figures, the left-most digit(s) of a reference number identifies the figure in which the reference number first appears. The use of the same reference numbers in different figures indicates similar or identical items.

FIGS. 1, 5, 6, and 7 illustrate block diagrams of embodiments of computing systems, which may be utilized to implement various embodiments discussed herein.

FIGS. 2A, 2B, and 4 show sample graphs relating to NAND devices, in accordance with some embodiments.

FIG. 3 illustrates a flow diagram of a method to switch between different trim profiles, in accordance with an embodiment.

### DETAILED DESCRIPTION

In the following description, numerous specific details are set forth in order to provide a thorough understanding of various embodiments. However, various embodiments may be practiced without the specific details. In other instances, well-known methods, procedures, components, and circuits have not been described in detail so as not to obscure the particular embodiments. Further, various aspects of embodiments may be performed using various means, such as integrated semiconductor circuits (“hardware”), computer-readable instructions organized into one or more programs (“software”), or some combination of hardware and software. For the purposes of this disclosure reference to “logic” shall mean either hardware, software, or some combination thereof.

As mentioned before, one major disadvantage of flash memory (such as NAND memory included in SSDs (Solid State Drives)) is that it offers a limited number of erase/program capability. As such, the NAND memory in an SSD degrades with higher program/erase cycles. However, NAND memory is expected to meet industry standard data retention, and write endurance requirements at all the cycle counts and operating conditions. NAND endurance is usually limited by write errors (also called as Program Disturb or simply PD,), thus optimizing or improving program disturb will improve overall NAND endurance. NAND PD shows strong dependence on the SSD operating temperature and usually the corner operating temperatures dictates the SSD PD reliability. SSD NAND endurance is generally characterized by measuring Raw Bit Error Rate (RBER), which refers to the fraction of data bits failing during a NAND read operation.

Some embodiments improve flash memory endurance using temperature based NAND settings. While NAND memory is generally discussed herein, embodiments are not limited to NAND memory and may be applicable to other types of flash memory (such as NOR flash memory). In an embodiment, current operating conditions are detected and used to dynamically select an appropriate trim profile to minimize potential errors at corner usage cases, while extending the overall flash memory endurance for typical usage. For example, an SSD drive's operating temperature information is used to select appropriate trim values for minimizing program disturb errors at higher temperature while extending the overall SSD endurance for a typical user.

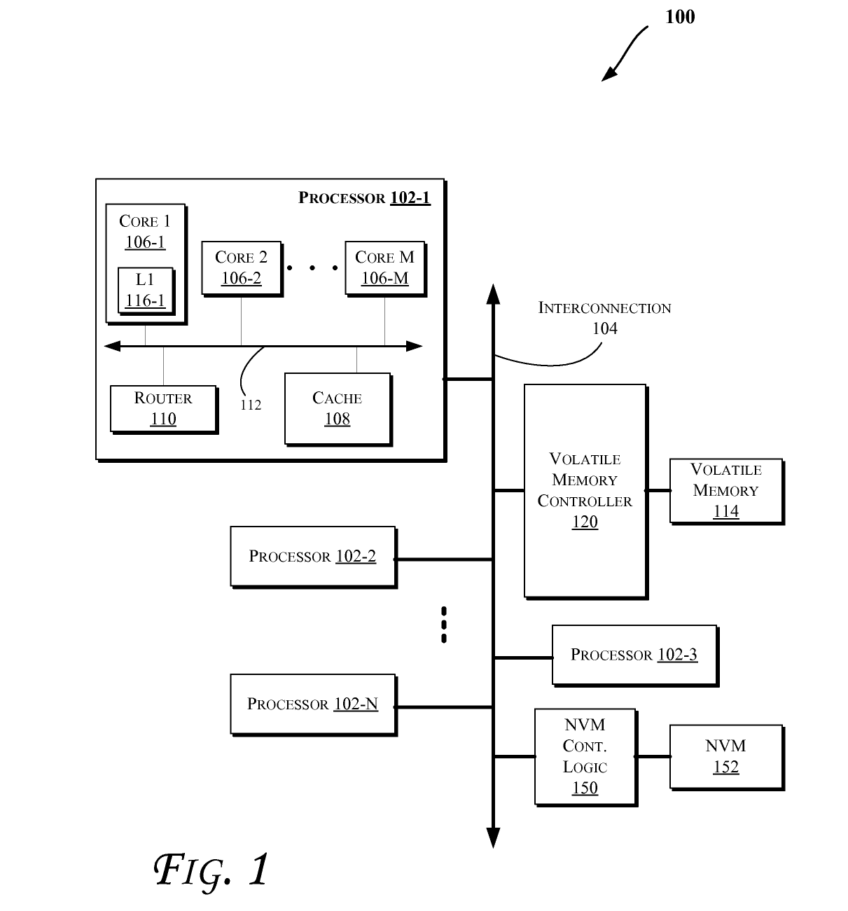

Moreover, the memory techniques discussed herein may be provided in various computing systems (e.g., including a mobile device such as a smartphone, tablet, UMPC (Ultra-Mobile Personal Computer), laptop computer, Ultrabook™ computing device, smart watch, smart glasses, etc.), such as those discussed with reference to FIGS. 1-7. More particularly, FIG. 1 illustrates a block diagram of a computing system 100, according to an embodiment. The system 100 includes one or more processors 102-1 through 102-N (generally referred to herein as “processors 102” or “processor 102”). The processors 102 may communicate via an interconnection or bus 104. Each processor may include various components some of which are only discussed with reference to processor 102-1 for clarity. Accordingly, each of the remaining processors 102-2 through 102-N may include the same or similar components discussed with reference to the processor 102-1.

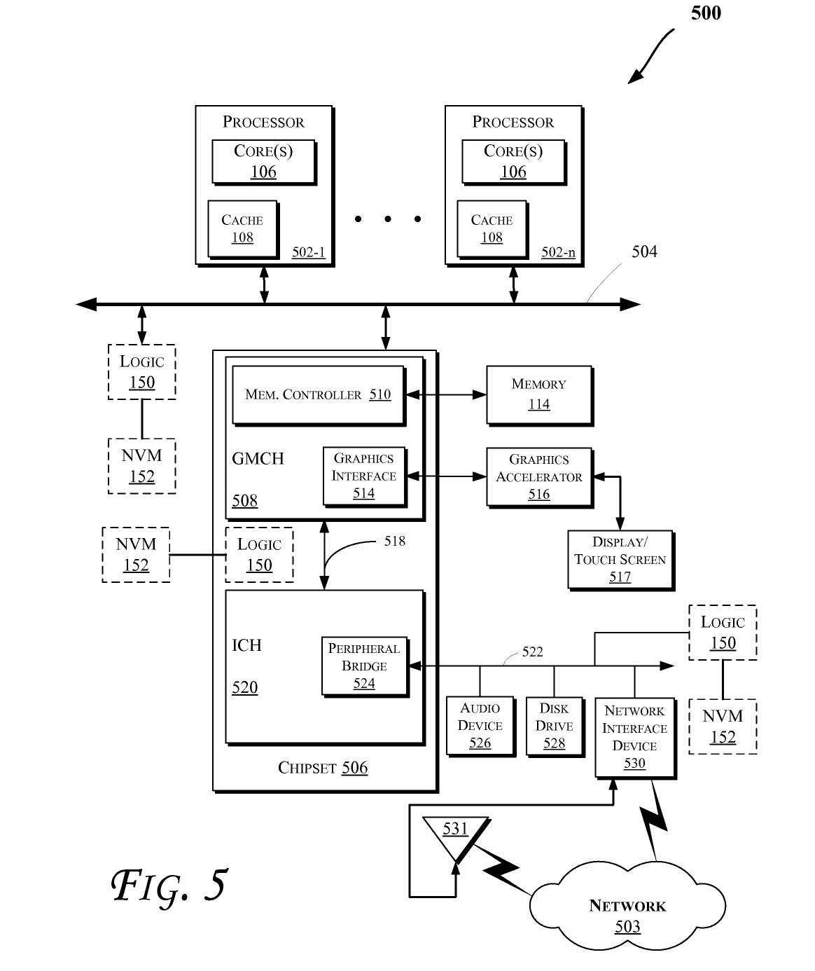

In an embodiment, the processor 102-1 may include one or more processor cores 106-1 through 106-M (referred to herein as “cores 106,” or more generally as “core 106”), a cache 108 (which may be a shared cache or a private cache in various embodiments), and/or a router 110. The processor cores 106 may be implemented on a single integrated circuit (IC) chip. Moreover, the chip may include one or more shared and/or private caches (such as cache 108), buses or interconnections (such as a bus or interconnection 112), logic 120, logic 150, memory controllers (such as those discussed with reference to FIGS. 5-7), NVM (Non-Volatile Memory) 152 (e.g., including flash memory, an SSD (with NAND memory cells)), etc., or other components.

In one embodiment, the router 110 may be used to communicate between various components of the processor 102-1 and/or system 100. Moreover, the processor 102-1 may include more than one router 110. Furthermore, the multitude of routers 110 may be in communication to enable data routing between various components inside or outside of the processor 102-1.

The cache 108 may store data (e.g., including instructions) that are utilized by one or more components of the processor 102-1, such as the cores 106. For example, the cache 108 may locally cache data stored in a volatile memory 114 for faster access by the components of the processor 102. As shown in FIG. 1, the memory 114 may be in communication with the processors 102 via the interconnection 104. In an embodiment, the cache 108 (that may be shared) may have various levels, for example, the cache 108 may be a mid-level cache and/or a last-level cache (LLC). Also, each of the cores 106 may include a level 1 (L1) cache (116-1) (generally referred to herein as “L1 cache 116”). Various components of the processor 102-1 may communicate with the cache 108 directly, through a bus (e.g., the bus 112), and/or a memory controller or hub.

As shown in FIG. 1, memory 114 may be coupled to other components of system 100 through a volatile memory controller 120. System 100 also includes NVM memory controller logic 150 to couple NVM memory 152 to various components of the system 100. Memory 152 includes non-volatile memory such as flash memory, Spin Torque Transfer Random Access Memory (STTRAM), Resistive Random Access Memory, 3D Cross Point Memory such as PCM (Phase Change Memory), an SSD with NAND memory, etc. in some embodiments. Even though the memory controller 150 is shown to be coupled between the interconnection 104 and the memory 152, the logic 150 may be located elsewhere in system 100. For example, logic 150 (or portions of it) may be provided within one of the processors 102, controller 120, etc. in various embodiments. In an embodiment, logic 150 and NVM 152 are included in an SSD. Moreover, logic 150 controls access to one or more NVM devices 152 (e.g., where the one or more NVM devices are provided on the same integrated circuit die in some embodiments), as discussed herein with respect to various embodiments.

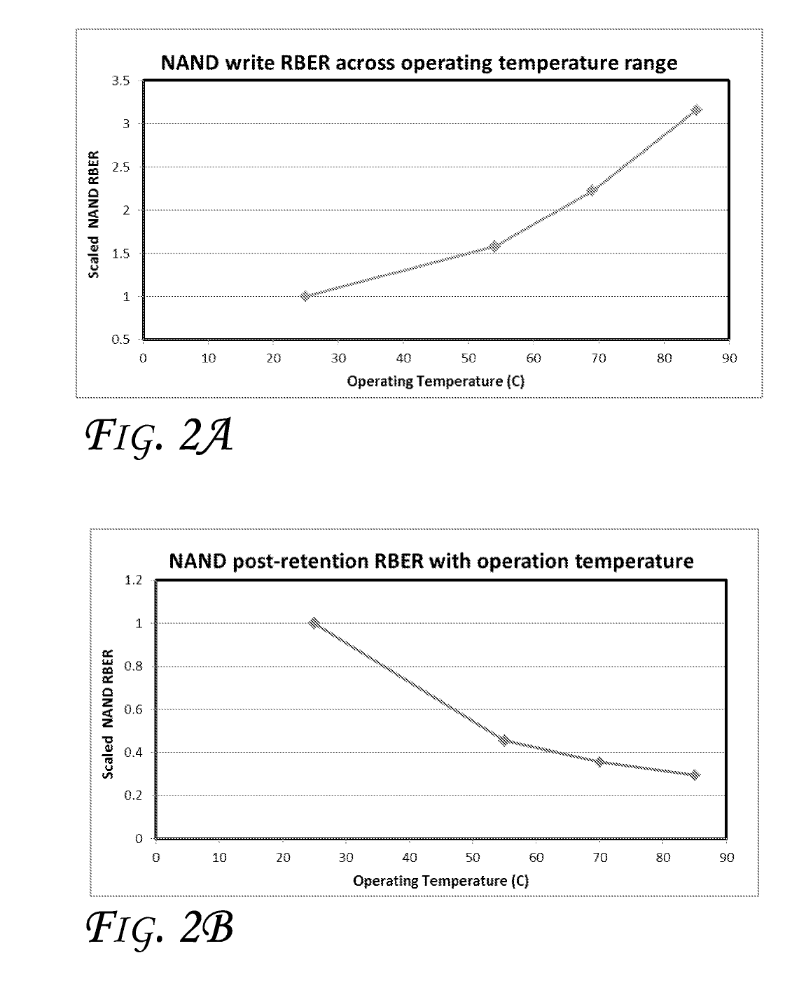

FIGS. 2A and 2B show sample behavior of NAND write RBER and NAND post-retention RBER over sample temperature range values. The values in FIGS. 2A-2B are for illustrative purposes and should not be used to limit the embodiments. As NAND temperatures rise, RBER increases and is usually the limiter for NAND PD (see, e.g., FIG. 2A). Also, as NAND temperatures rise, NAND post retention drops (see, e.g., FIG. 2B). Moreover, NAND trim profiles are generally optimized to meet both PD goals at higher temperature (corner case) and data retention goals at lower temperature. Current SSDs generally use fixed NAND settings across an operating temperature range and, thus, these settings are optimized to meet NAND endurance goals across all corner cases, as well as usage conditions, and are not necessarily optimized for each corner case individually. One main reason for this is that current drive operating conditions may not be sensed or monitored in the SSDs and, as a result, a single NAND setting is used to meet all the cases.

To this end, in an embodiment, current operating conditions are detected and used to dynamically select an appropriate trim profile to minimize potential errors at corner usage cases, while extending the overall flash memory endurance for typical usage. For example, a flash drive's operating temperature information is used to select appropriate trim values for minimizing program disturb errors at higher temperature, while extending the overall drive endurance for a typical user. In this case, by using trims optimized for PD at hot temperatures (e.g., FIG. 2A) and for data retention at room temperature (e.g., FIG. 2B), overall NAND endurance can be extended.

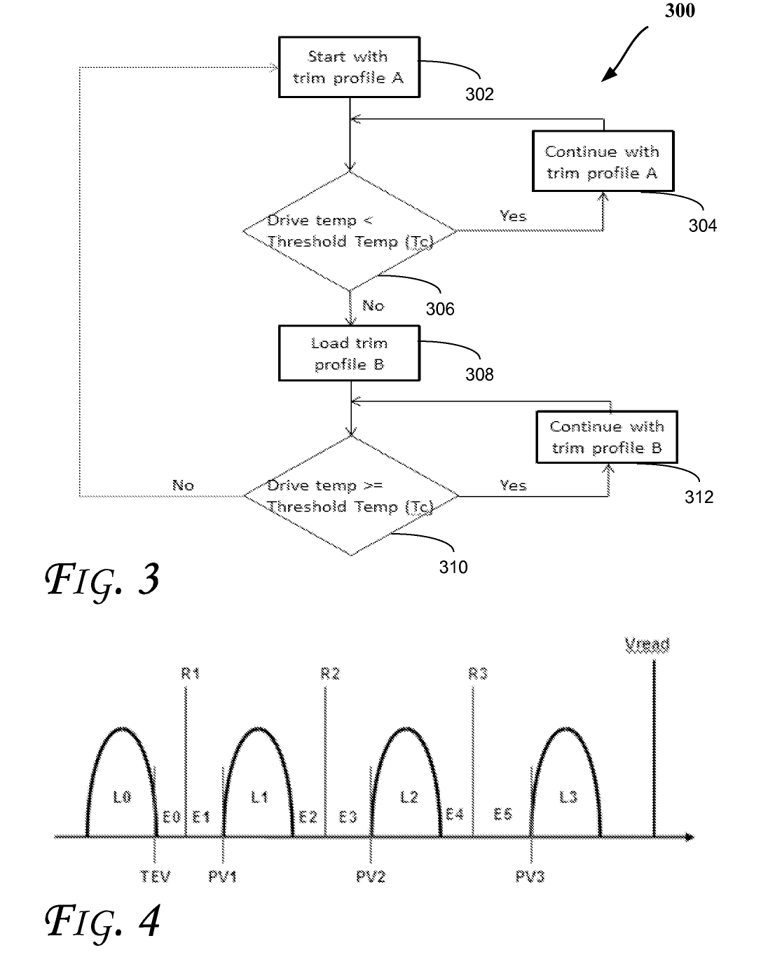

Most SSDs have a reliable temperature sensor on the board (e.g., thermally proximate to or thermally coupled to the NVM/NAND flash memory 152 and/or controller logic 150) and SSD firmware can have access to instantaneous operating temperature of the drive. Using the available instantaneous drive temperature data, firmware may load new NAND trim profile if drive temperature rises above some threshold temperature and thus improve NAND reliability at corner temperature cases, as will be further discussed with reference to FIG. 3. These new trim profiles may have performance/reliability downside(s) associated with them, but since the SSD drive will be operating above threshold temperature only for a small fraction of its lifetime, the downside(s) may not be noticeable to end users.

As discussed herein a “trim profile” generally refers to pre-defined setting(s) for NVM/NAND memory parameters (e.g., which may be stored in a storage unit (such as a non-volatile memory) in each NAND die or in the NAND flash controller in the SSD). These settings are used for NAND/NVM operations. For example, a trim profile may include settings for parameters such as WL/BL (Word Line/Bit Line) voltages during array operations (e.g., program/erase/read/etc.), program verify levels, read reference values, maximum WL bias value, array operation timeout period, etc.

FIG. 3 illustrates a flow diagram of a method 300 to switch between different trim profiles, in accordance with an embodiment. In an embodiment, various components discussed with reference to FIGS. 1-2 and 4-7 may be utilized to perform one or more of the operations discussed with reference to FIG. 3. In an embodiment, method 300 is implemented in logic (e.g., firmware).

Generally, a NAND device uses fixed settings to optimize NAND operations and these settings are referred to as “trim profile.” Referring to FIGS. 1-3, at an operation 302, a first trim profile (e.g., profile A) is applied to the NVM 152 (e.g., SSD/NAND drive). The SSD drive will continue to use this trim profile (e.g., operation 304) as long as drive temperature (e.g., as sensed by an on-drive temperature sensor (not shown)) is less than some fixed threshold temperature (Tc) at determined at an operation 306. Once the threshold temp is reached at operation 306, an operation 308 loads a different trim profile B (e.g., by the controller logic 150). As long as the sensed drive temperature stays above the threshold temperature value (Tc), as determined at an operation 310, the drive continues with trim profile B at operation 312. Once the sense drive temperature drops below the threshold temperature value (Tc) as determined at operation 310, trim profile A is reloaded at operation 302.

Accordingly, if SSD drive temperature rises above Tc, SSD will load trim profile B (which may be stored in a storage unit (such as a non-volatile memory) in each NAND die or in the NAND flash controller in the SSD) and continues to use it as long as drive temperature is above Tc. Once drive temperature falls below Tc, drive will reset back to trim profile A. Using trim profile B, NAND will improve high temperature reliability. This implementation shows only single temperature check point (two operating ranges/profiles) but actual implementation may use more than one temperature check point and thus multiple trim profiles. While FIG. 3 only discusses two trim profiles, embodiments are not limited to two trim profiles and more than two trim profiles (and corresponding temperature threshold values) may be used in various embodiments. For example, three trim profiles with two temperature threshold values may be used, e.g., where profile A is applied for drive temperatures of less than Tc1, profile B is used for drive temperatures between Tc1 and Tc2, and profile C is used for drive temperatures above Tc2, and so on.

FIG. 4 illustrates NAND MLC (Multi Level Cell) programming level distributions, according to some implementations. In FIG. 4, the horizontal axis represents threshold level voltage (Vt). Four MLC levels (L0-L3), three read reference levels (R1-R3), a sample erase verify (TEV), and program verify (PV1, PV2, PV3) voltages are shown that define a NAND MLC window, in accordance with some implementations. More particularly, a two-bit per cell window is shown where each cell may be programmed to any of four states. Upon erase, all cells in a block are erased to a threshold voltage (Vt) below TEV. Then, the cells in the array are programmed to L1, L2, or L3, by placing the Vt above PV1, PV2, PV3, respectively.

Moreover, the read reference voltages (R1, R2, R3) and the state widths of the placed distributions determine the edge margins available. The even edges E0, E2, E4 determine the margin for program disturb and over-program, while the odd edges E1, E3, E5 determine the margin for charge loss. The sum of the edge margins E0 through E5 in FIG. 4 is usually defined as the Read Window Budget (RWB). A larger window between PV3 and TEV allows larger margins for E0 to E5, e.g., to read the cell correctly in the even of charge loss or disturb/over-program. The PV3 to TEV window is designed such that the above-mentioned margins will meet reliability requirements for a cycled block (end of life), which are generally worse than those for an un-cycled block.

Moreover, one or more of the following techniques may be applied for trim profile B (of FIG. 3) to improve program disturb performance at higher temperatures, in various embodiments:

(1) Trade data retention margin for PD: For example, as shown in FIG. 4. PD RBER is improved if we have a higher E0 margin. By trading an odd edge margin (which is used for data retention) for E0, PD RBER at higher temperature can be improved as data retention RBER is lower at higher operating temperatures (see, e.g., FIG. 2B). In case operating temperature drops lower, these blocks with lower data retention margin can be refreshed faster using a background data refresh scheme to ensure that they meet data retention goals. One potential upside is that PD RBER can be improved by ˜3× (e.g., best case) by flattening out the temperature dependence (see, e.g., FIG. 2A). This translates to ˜1.7-3× improvement in NAND cycling endurance capability depending on NAND process node.

(2) Erase deeper to improve E0 margin: By lowering erase verify level (TEV), L0 distribution can be moved down, thus, giving higher E0 margin. As the drive temperature rises above Tc, logic (e.g., logic 150, logic within NVM 152, firmware, etc.) can erase available unused bands with lower TEV (deeper erase) and use them for subsequent write at higher temperature. One potential upside is that, erasing deeper can buy extra PD margin. Minimum TEV setting possible will be limited by raw erase fail endurance. Estimated (e.g., best case) is that ˜1.4-2× cycling capability upside may be provided based on this data.

(3) Dynamic change to SLC/1.5 bpc (where SLC refers to Single Level Cell): logic (e.g., logic 150, logic on-board NVM 152, firmware, etc.) can load a trim profile to change to SLC or 1.5 bpc mode on-the-fly at higher temperatures, e.g., where PD reliability is much higher. One potential upside is that SLC/1.5 bpc show >3× PD RBER upside compared to MLC mode. This implementation can help minimize the high temperature degradation seen on PD. Best case upside may be ˜3× in PD RBER, which translates to ˜1.7-3× in cycling capability.

(4) Optimize trim settings for lower temperatures: NAND trim settings are optimized for highest operating temperature as PD RBER is worst at that condition (see, e.g., FIG. 2A). Usually by optimizing trim settings for highest operating temperature, NAND reliability for non-PD cases is sacrificed. With this implementation, NAND can use trim profiles optimized for room temperature and high temperature settings only when needed (e.g., when drive temperature rises above Tc), thus, extending overall NAND reliability. One potential upside is that based on 24 nm Silicon data, optimizing lower temperature trims to improve post retention errors may improve retention capability by about 1.4× cycles.

(5) Slower program trims: By using slower program trims at higher temperatures, logic (e.g., logic 150, logic on-board NVM 152, firmware, etc.) can tighten NAND program level distributions (L1-L3 in FIG. 4) and thus increase overall RWB margin (RWB margin is total margin in-between MLC levels L0 through L3). This increase in RWB margin can be used to increase available E0 margin, improving PD RBER. One potential upside is that some data shows ˜1.2× improvement in cycling capability with ˜15% program performance impact.

(6) Dynamic Vread: During read, Vread (read voltage) voltage is applied to unselected word-lines to turn them on (see, e.g., FIG. 4). Higher Vread voltage lowers the effective resistance of the bit-line and improves the total RWB margin (Total RWB margin is the sum of all edge margins shown in FIG. 4). Read disturb reliability limits the maximum Vread voltage allowed for a technology. In this implementation, Vread can be increased at higher temperatures and extra RWB margin can be used to improve PD RBER. Penalty may be increased for read disturb relocations in the drive (which may have a performance impact) at higher temperatures. One potential upside is a gain of about 1.4× in cycling capability with ˜400% read performance impact at higher temperatures.

(7) Dynamic read settings: Even though data retention capability improves with higher operating temperature, it becomes worse when the readout temperature is higher than the operating temperature of the drive (for example, a reading drive at hot temp after room temperature operation). In that case, drive firmware/logic (e.g., logic 150, logic on-board NVM 152, firmware, etc.) can shift the read reference voltages (R1, R2 and R3 in FIG. 4) to account for lower odd edge margins at hot temperatures. Logic can also fill any partially written blocks to improve their data retention capability (e.g., as partially filled blocks show worse data retention capability than fully programmed blocks). A potential upside is that shifting read references will improve the drive read performance by minimizing ECC (Error Correcting Code) fail triggers. Filling a partially programmed block will help improve data retention margins. Based on some current product data, this may help improve cycling capability (assuming data retention is the limiter) by ˜20%.

FIG. 5 illustrates a block diagram of a computing system 500 in accordance with an embodiment of the invention. The computing system 500 may include one or more central processing unit(s) (CPUs) 502 or processors that communicate via an interconnection network (or bus) 504. The processors 502 may include a general purpose processor, a network processor (that processes data communicated over a computer network 503), an application processor (such as those used in cell phones, smart phones, etc.), or other types of a processor (including a reduced instruction set computer (RISC) processor or a complex instruction set computer (CISC)). Various types of computer networks 503 may be utilized including wired (e.g., Ethernet, Gigabit, Fiber, etc.) or wireless networks (such as cellular, 3G (Third-Generation Cell-Phone Technology or 3rd Generation Wireless Format (UWCC)), 5G, Low Power Embedded (LPE), etc.). Moreover, the processors 502 may have a single or multiple core design. The processors 502 with a multiple core design may integrate different types of processor cores on the same integrated circuit (IC) die. Also, the processors 502 with a multiple core design may be implemented as symmetrical or asymmetrical multiprocessors.

In an embodiment, one or more of the processors 502 may be the same or similar to the processors 102 of FIG. 1. For example, one or more of the processors 502 may include one or more of the cores 106 and/or cache 108. Also, the operations discussed with reference to FIGS. 1-4 may be performed by one or more components of the system 500.

A chipset 506 may also communicate with the interconnection network 504. The chipset 506 may include a graphics and memory control hub (GMCH) 508. The GMCH 508 may include a memory controller 510 (which may be the same or similar to the memory controller 120 of FIG. 1 in an embodiment) that communicates with the memory 114. System 500 may also include logic 150 (e.g., coupled to NVM 152) in various locations (such as those shown in FIG. 5 but can be in other locations within system 500 (not shown)). The memory 114 may store data, including sequences of instructions that are executed by the CPU 502, or any other device included in the computing system 500. In one embodiment of the invention, the memory 114 may include one or more volatile storage (or memory) devices such as random access memory (RAM), dynamic RAM (DRAM), synchronous DRAM (SDRAM), static RAM (SRAM), or other types of storage devices. Nonvolatile memory may also be utilized such as a hard disk, flash, 3D Cross Point Memory (such as PCM), Resistive Random Access Memory, NAND memory, NOR memory and STTRAM. Additional devices may communicate via the interconnection network 504, such as multiple CPUs and/or multiple system memories.

The GMCH 508 may also include a graphics interface 514 that communicates with a graphics accelerator 516. In one embodiment of the invention, the graphics interface 514 may communicate with the graphics accelerator 516 via an accelerated graphics port (AGP) or Peripheral Component Interconnect (PCI) (or PCI express (PCIe) interface). In an embodiment of the invention, a display 517 (such as a flat panel display, touch screen, etc.) may communicate with the graphics interface 514 through, for example, a signal converter that translates a digital representation of an image stored in a storage device such as video memory or system memory into display signals that are interpreted and displayed by the display. The display signals produced by the display device may pass through various control devices before being interpreted by and subsequently displayed on the display 517.

A hub interface 518 may allow the GMCH 508 and an input/output control hub (ICH) 520 to communicate. The ICH 520 may provide an interface to I/O devices that communicate with the computing system 500. The ICH 520 may communicate with a bus 522 through a peripheral bridge (or controller) 524, such as a peripheral component interconnect (PCI) bridge, a universal serial bus (USB) controller, or other types of peripheral bridges or controllers. The bridge 524 may provide a data path between the CPU 502 and peripheral devices. Other types of topologies may be utilized. Also, multiple buses may communicate with the ICH 520, e.g., through multiple bridges or controllers. Moreover, other peripherals in communication with the ICH 520 may include, in various embodiments, integrated drive electronics (IDE) or small computer system interface (SCSI) hard drive(s), USB port(s), a keyboard, a mouse, parallel port(s), serial port(s), floppy disk drive(s), digital output support (e.g., digital video interface (DVI)), or other devices.

The bus 522 may communicate with an audio device 526, one or more disk drive(s) 528, and a network interface device 530 (which is in communication with the computer network 503, e.g., via a wired or wireless interface). As shown, the network interface device 530 may be coupled to an antenna 531 to wirelessly (e.g., via an Institute of Electrical and Electronics Engineers (IEEE) 802.11 interface (including IEEE 802.11a/b/g/n, etc.), cellular interface, 3G, 5G, LPE, etc.) communicate with the network 503. Other devices may communicate via the bus 522. Also, various components (such as the network interface device 530) may communicate with the GMCH 508 in some embodiments. In addition, the processor 502 and the GMCH 508 may be combined to form a single chip. Furthermore, the graphics accelerator 516 may be included within the GMCH 508 in other embodiments.

Furthermore, the computing system 500 may include volatile and/or nonvolatile memory (or storage). For example, nonvolatile memory may include one or more of the following: read-only memory (ROM), programmable ROM (PROM), erasable PROM (EPROM), electrically EPROM (EEPROM), a disk drive (e.g., 528), a floppy disk, a compact disk ROM (CD-ROM), a digital versatile disk (DVD), flash memory, a magneto-optical disk, or other types of nonvolatile machine-readable media that are capable of storing electronic data (e.g., including instructions).

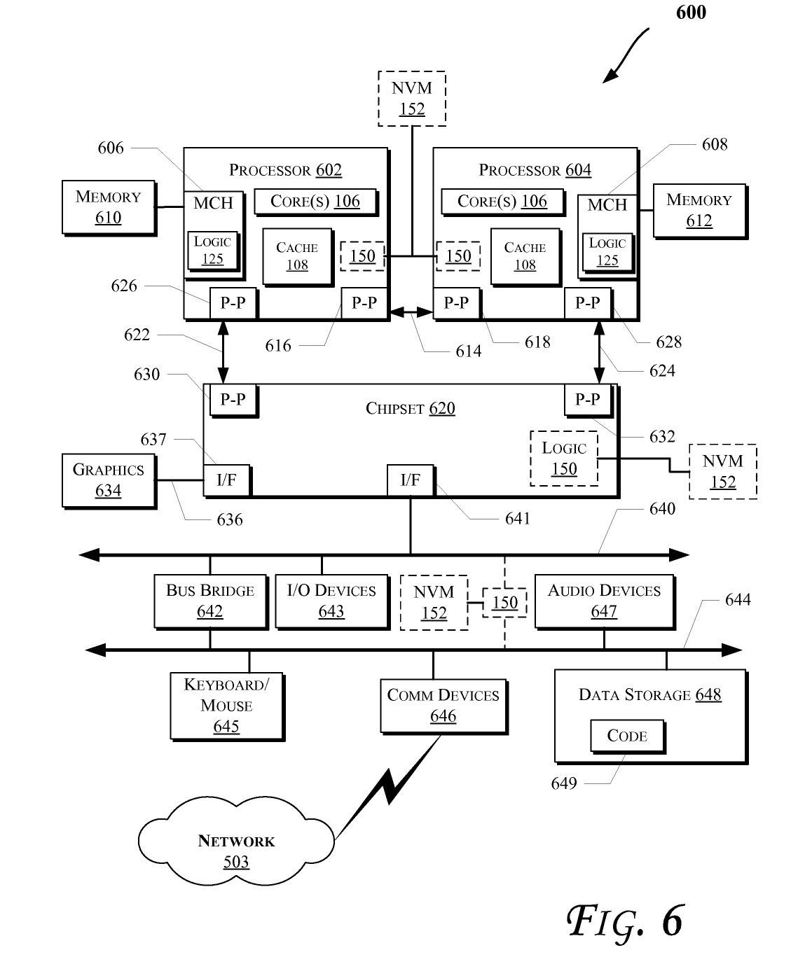

FIG. 6 illustrates a computing system 600 that is arranged in a point-to-point (PtP) configuration, according to an embodiment. In particular, FIG. 6 shows a system where processors, memory, and input/output devices are interconnected by a number of point-to-point interfaces. The operations discussed with reference to FIGS. 1-5 may be performed by one or more components of the system 600.

As illustrated in FIG. 6, the system 600 may include several processors, of which only two, processors 602 and 604 are shown for clarity. The processors 602 and 604 may each include a local memory controller hub (MCH) 606 and 608 to enable communication with memories 610 and 612. The memories 610 and/or 612 may store various data such as those discussed with reference to the memory 114 or NVM 152 of FIGS. 1 and/or 5. Also, MCH 606 and 608 may include the memory controller 120 and/or logic 150 of FIG. 1 in some embodiments.

In an embodiment, the processors 602 and 604 may be one of the processors 502 discussed with reference to FIG. 5. The processors 602 and 604 may exchange data via a point-to-point (PtP) interface 614 using PtP interface circuits 616 and 618, respectively. Also, the processors 602 and 604 may each exchange data with a chipset 620 via individual PtP interfaces 622 and 624 using point-to-point interface circuits 626, 628, 630, and 632. The chipset 620 may further exchange data with a high-performance graphics circuit 634 via a high-performance graphics interface 636, e.g., using a PtP interface circuit 637. As discussed with reference to FIG. 5, the graphics interface 636 may be coupled to a display device (e.g., display 517) in some embodiments.

As shown in FIG. 6, one or more of the cores 106 and/or cache 108 of FIG. 1 may be located within the processors 602 and 604. Other embodiments, however, may exist in other circuits, logic units, or devices within the system 600 of FIG. 6. Furthermore, other embodiments may be distributed throughout several circuits, logic units, or devices illustrated in FIG. 6.

The chipset 620 may communicate with a bus 640 using a PtP interface circuit 641. The bus 640 may have one or more devices that communicate with it, such as a bus bridge 642 and I/O devices 643. Via a bus 644, the bus bridge 642 may communicate with other devices such as a keyboard/mouse 645, communication devices 646 (such as modems, network interface devices, or other communication devices that may communicate with the computer network 503, as discussed with reference to network interface device 530 for example, including via antenna 531), audio I/O device, and/or a data storage device 648. The data storage device 648 may store code 649 that may be executed by the processors 602 and/or 604.

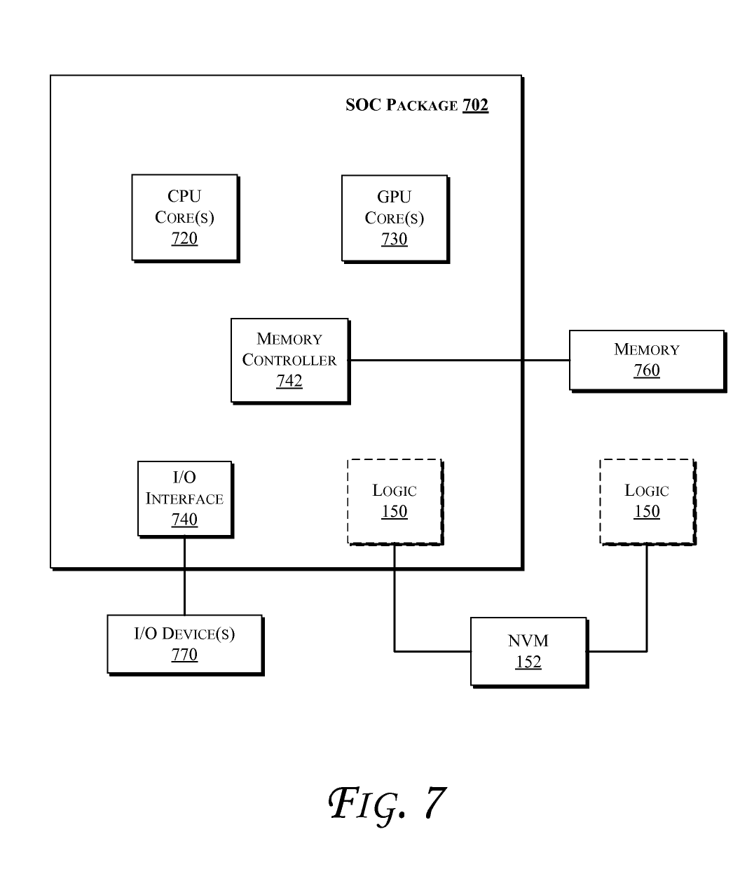

In some embodiments, one or more of the components discussed herein can be embodied as a System On Chip (SOC) device. FIG. 7 illustrates a block diagram of an SOC package in accordance with an embodiment. As illustrated in FIG. 7, SOC 702 includes one or more Central Processing Unit (CPU) cores 720, one or more Graphics Processor Unit (GPU) cores 730, an Input/Output (I/O) interface 740, and a memory controller 742. Various components of the SOC package 702 may be coupled to an interconnect or bus such as discussed herein with reference to the other figures. Also, the SOC package 702 may include more or less components, such as those discussed herein with reference to the other figures. Further, each component of the SOC package 720 may include one or more other components, e.g., as discussed with reference to the other figures herein. In one embodiment, SOC package 702 (and its components) is provided on one or more Integrated Circuit (IC) die, e.g., which are packaged onto a single semiconductor device.

As illustrated in FIG. 7, SOC package 702 is coupled to a memory 760 (which may be similar to or the same as memory discussed herein with reference to the other figures) via the memory controller 742. In an embodiment, the memory 760 (or a portion of it) can be integrated on the SOC package 702.

The I/O interface 740 may be coupled to one or more I/O devices 770, e.g., via an interconnect and/or bus such as discussed herein with reference to other figures. I/O device(s) 770 may include one or more of a keyboard, a mouse, a touchpad, a display, an image/video capture device (such as a camera or camcorder/video recorder), a touch screen, a speaker, or the like. Furthermore, SOC package 702 may include/integrate the logic 150 in an embodiment. Alternatively, the logic 150 may be provided outside of the SOC package 702 (i.e., as a discrete logic).

The following examples pertain to further embodiments. Example 1 includes an apparatus comprising: memory controller logic to apply one of a first trim profile or a second trim profile to a flash memory storage device based at least partially on a comparison of a threshold temperature value and a sensed temperature of the flash memory storage device. Example 2 includes the apparatus of example 1, further comprising a temperature sensor, thermally proximate to the flash memory storage device, to detect the sensed temperature. Example 3 includes the apparatus of example 1, wherein the flash memory storage device is to comprise a NAND flash memory or a NOR flash memory. Example 4 includes the apparatus of example 1, wherein the flash memory storage device is to be programmed based at least partially on one or more Multi Level Cell (MLC) voltage levels. Example 5 includes the apparatus of example 1, wherein the memory controller logic is to apply the first trim profile to the flash memory storage device based at least partially on a subsequent comparison of the threshold temperature value and a subsequent sensed temperature of the flash memory storage device, wherein the subsequent sensed temperature value of the flash memory storage device is to be higher than the sensed temperature of the flash memory storage device. Example 6 includes the apparatus of example 1, wherein the memory controller logic is to apply a third trim profile to the flash memory storage device based at least partially on a subsequent comparison of a subsequent threshold temperature value and a subsequent sensed temperature of the flash memory storage device. Example 7 includes the apparatus of example 1, wherein one or more processor cores are coupled to the memory controller logic to access data stored in the flash memory storage device. Example 8 includes the apparatus example 1, wherein the memory controller logic is to perform one or more of the following adjustments to the first or second trim profiles: trade a data retention margin for program disturb (PD), erase deeper to improve a first edge margin, dynamically change to Single Level Cell (SLC) mode, optimize trim settings for lower temperatures, provide slower program trims, or dynamically adjust read voltage.

Example 9 includes a method comprising: applying one of a first trim profile or a second trim profile to a flash memory storage device based at least partially on a comparison of a threshold temperature value and a sensed temperature of the flash memory storage device. Example 10 includes the method of example 9, further comprising detecting the sensed temperature at a temperature sensor that is thermally proximate to the flash memory storage device. Example 11 includes the method of example 9, wherein the flash memory storage device comprises a NAND flash memory or a NOR flash memory. Example 12 includes the method of example 9, further comprising programming the flash memory storage device based at least partially on one or more Multi Level Cell (MLC) voltage levels. Example 13 includes the method of example 9, further comprising applying the first trim profile to the flash memory storage device based at least partially on a subsequent comparison of the threshold temperature value and a subsequent sensed temperature of the flash memory storage device, wherein the subsequent sensed temperature value of the flash memory storage device is higher than the sensed temperature of the flash memory storage device. Example 14 includes the method of example 9, further comprising applying a third trim profile to the flash memory storage device based at least partially on a subsequent comparison of a subsequent threshold temperature value and a subsequent sensed temperature of the flash memory storage device. Example 15 includes the method of example 9, further comprising performing one or more of the following adjustments to the first or second trim profiles: trade a data retention margin for program disturb (PD), erase deeper to improve a first edge margin, dynamically change to Single Level Cell (SLC) mode, optimize trim settings for lower temperatures, provide slower program trims, or dynamically adjust read voltage.

Example 16 includes a computer-readable medium comprising one or more instructions that when executed on a processor configure the processor to perform one or more operations to: apply one of a first trim profile or a second trim profile to a flash memory storage device based at least partially on a comparison of a threshold temperature value and a sensed temperature of the flash memory storage device. Example 17 includes the computer-readable medium of example 16, further comprising one or more instructions that when executed on the processor configure the processor to perform one or more operations to cause detection of the sensed temperature at a temperature sensor that is thermally proximate to the flash memory storage device. Example 18 includes the computer-readable medium of example 16, wherein the flash memory storage device comprises a NAND flash memory or a NOR flash memory. Example 19 includes the computer-readable medium of example 16, further comprising one or more instructions that when executed on the processor configure the processor to perform one or more operations to cause programming of the flash memory storage device based at least partially on one or more Multi Level Cell (MLC) voltage levels. Example 20 includes the computer-readable medium of example 16, further comprising one or more instructions that when executed on the processor configure the processor to perform one or more operations to cause application of the first trim profile to the flash memory storage device based at least partially on a subsequent comparison of the threshold temperature value and a subsequent sensed temperature of the flash memory storage device, wherein the subsequent sensed temperature value of the flash memory storage device is higher than the sensed temperature of the flash memory storage device. Example 21 includes the computer-readable medium of example 16, further comprising one or more instructions that when executed on the processor configure the processor to perform one or more operations to cause application of a third trim profile to the flash memory storage device based at least partially on a subsequent comparison of a subsequent threshold temperature value and a subsequent sensed temperature of the flash memory storage device. Example 22 includes the computer-readable medium of example 16, further comprising one or more instructions that when executed on the processor configure the processor to perform one or more operations to cause performance of one or more of the following adjustments to the first or second trim profiles: trade a data retention margin for program disturb (PD), erase deeper to improve a first edge margin, dynamically change to Single Level Cell (SLC) mode, optimize trim settings for lower temperatures, provide slower program trims, or dynamically adjust read voltage.

Example 23 includes a system comprising: a NAND flash memory device having a plurality of memory cells; a processor to access the NAND flash memory device; and NAND flash memory controller logic, coupled to the NAND flash memory device, to apply one of a first trim profile or a second trim profile to the NAND flash memory device based at least partially on a comparison of a threshold temperature value and a sensed temperature of the NAND flash memory device. Example 24 includes the system of example 23, further comprising a temperature sensor, thermally proximate to the NAND flash memory device, to detect the sensed temperature. Example 25 includes the system of example 23, wherein the NAND flash memory device is to be programmed based at least partially on one or more Multi Level Cell (MLC) voltage levels.

Example 26 includes a computer-readable medium comprising one or more instructions that when executed on a processor configure the processor to perform one or more operations of any of examples 9 to 15.

Example 27 includes an apparatus comprising means to perform a method as set forth in any of examples 9 to 15.

Example 28 includes the apparatus of any of examples 1 to 7, wherein the memory controller logic is to perform one or more of the following adjustments to the first or second trim profiles: trade a data retention margin for program disturb (PD), erase deeper to improve a first edge margin, dynamically change to Single Level Cell (SLC) mode, optimize trim settings for lower temperatures, provide slower program trims, or dynamically adjust read voltage.

In various embodiments, the operations discussed herein, e.g., with reference to FIGS. 1-7, may be implemented as hardware (e.g., circuitry), software, firmware, microcode, or combinations thereof, which may be provided as a computer program product, e.g., including a tangible (e.g., non-transitory) machine-readable or computer-readable medium having stored thereon instructions (or software procedures) used to program a computer to perform a process discussed herein. Also, the term “logic” may include, by way of example, software, hardware, or combinations of software and hardware. The machine-readable medium may include a storage device such as those discussed with respect to FIGS. 1-7.

Additionally, such tangible computer-readable media may be downloaded as a computer program product, wherein the program may be transferred from a remote computer (e.g., a server) to a requesting computer (e.g., a client) by way of data signals (such as in a carrier wave or other propagation medium) via a communication link (e.g., a bus, a modem, or a network connection).

Reference in the specification to “one embodiment” or “an embodiment” means that a particular feature, structure, or characteristic described in connection with the embodiment may be included in at least an implementation. The appearances of the phrase “in one embodiment” in various places in the specification may or may not be all referring to the same embodiment.

Also, in the description and claims, the terms “coupled” and “connected,” along with their derivatives, may be used. In some embodiments, “connected” may be used to indicate that two or more elements are in direct physical or electrical contact with each other. “Coupled” may mean that two or more elements are in direct physical or electrical contact. However, “coupled” may also mean that two or more elements may not be in direct contact with each other, but may still cooperate or interact with each other.

Thus, although embodiments have been described in language specific to structural features and/or methodological acts, it is to be understood that claimed subject matter may not be limited to the specific features or acts described. Rather, the specific features and acts are disclosed as sample forms of implementing the claimed subject matter.

1. An apparatus comprising:
memory controller logic to apply one of a first trim profile or a second trim profile to a flash memory storage device based at least partially on a comparison of a threshold temperature value and a sensed temperature of the flash memory storage device.

2. The apparatus of claim 1, further comprising a temperature sensor, thermally proximate to the flash memory storage device, to detect the sensed temperature.

3. The apparatus of claim 1, wherein the flash memory storage device is to comprise a NAND flash memory or a NOR flash memory.

4. The apparatus of claim 1, wherein the flash memory storage device is to be programmed based at least partially on one or more Multi Level Cell (MLC) voltage levels.

5. The apparatus of claim 1, wherein the memory controller logic is to apply the first trim profile to the flash memory storage device based at least partially on a subsequent comparison of the threshold temperature value and a subsequent sensed temperature of the flash memory storage device, wherein the subsequent sensed temperature value of the flash memory storage device is to be higher than the sensed temperature of the flash memory storage device.

6. The apparatus of claim 1, wherein the memory controller logic is to apply a third trim profile to the flash memory storage device based at least partially on a subsequent comparison of a subsequent threshold temperature value and a subsequent sensed temperature of the flash memory storage device.

7. The apparatus of claim 1, wherein the memory controller logic is to perform one or more of the following adjustments to the first or second trim profiles: trade a data retention margin for program disturb (PD), erase deeper to improve a first edge margin, dynamically change to Single Level Cell (SLC) mode, optimize trim settings for lower temperatures, provide slower program trims, or dynamically adjust read voltage.

8. The apparatus of claim 1, wherein one or more processor cores are coupled to the memory controller logic to access data stored in the flash memory storage device.

9. A method comprising:
applying one of a first trim profile or a second trim profile to a flash memory storage device based at least partially on a comparison of a threshold temperature value and a sensed temperature of the flash memory storage device.

10. The method of claim 9, further comprising detecting the sensed temperature at a temperature sensor that is thermally proximate to the flash memory storage device.

11. The method of claim 9, wherein the flash memory storage device comprises a NAND flash memory or a NOR flash memory.

12. The method of claim 9, further comprising programming the flash memory storage device based at least partially on one or more Multi Level Cell (MLC) voltage levels.

13. The method of claim 9, further comprising applying the first trim profile to the flash memory storage device based at least partially on a subsequent comparison of the threshold temperature value and a subsequent sensed temperature of the flash memory storage device, wherein the subsequent sensed temperature value of the flash memory storage device is higher than the sensed temperature of the flash memory storage device.

14. The method of claim 9, further comprising applying a third trim profile to the flash memory storage device based at least partially on a subsequent comparison of a subsequent threshold temperature value and a subsequent sensed temperature of the flash memory storage device.

15. The method of claim 9, further comprising performing one or more of the following adjustments to the first or second trim profiles: trade a data retention margin for program disturb (PD), erase deeper to improve a first edge margin, dynamically change to Single Level Cell (SLC) mode, optimize trim settings for lower temperatures, provide slower program trims, or dynamically adjust read voltage.

16. A computer-readable medium comprising one or more instructions that when executed on a processor configure the processor to perform one or more operations to:
apply one of a first trim profile or a second trim profile to a flash memory storage device based at least partially on a comparison of a threshold temperature value and a sensed temperature of the flash memory storage device.

17. The computer-readable medium of claim 16, further comprising one or more instructions that when executed on the processor configure the processor to perform one or more operations to cause detection of the sensed temperature at a temperature sensor that is thermally proximate to the flash memory storage device.

18. The computer-readable medium of claim 16, wherein the flash memory storage device comprises a NAND flash memory or a NOR flash memory.

19. The computer-readable medium of claim 16, further comprising one or more instructions that when executed on the processor configure the processor to perform one or more operations to cause programming of the flash memory storage device based at least partially on one or more Multi Level Cell (MLC) voltage levels.

20. The computer-readable medium of claim 16, further comprising one or more instructions that when executed on the processor configure the processor to perform one or more operations to cause application of the first trim profile to the flash memory storage device based at least partially on a subsequent comparison of the threshold temperature value and a subsequent sensed temperature of the flash memory storage device, wherein the subsequent sensed temperature value of the flash memory storage device is higher than the sensed temperature of the flash memory storage device.

21. The computer-readable medium of claim 16, further comprising one or more instructions that when executed on the processor configure the processor to perform one or more operations to cause application of a third trim profile to the flash memory storage device based at least partially on a subsequent comparison of a subsequent threshold temperature value and a subsequent sensed temperature of the flash memory storage device.

22. The computer-readable medium of claim 16, further comprising one or more instructions that when executed on the processor configure the processor to perform one or more operations to cause performance of one or more of the following adjustments to the first or second trim profiles: trade a data retention margin for program disturb (PD), erase deeper to improve a first edge margin, dynamically change to Single Level Cell (SLC) mode, optimize trim settings for lower temperatures, provide slower program trims, or dynamically adjust read voltage.

23. A system comprising:
a NAND flash memory device having a plurality of memory cells;
a processor to access the NAND flash memory device; and
NAND flash memory controller logic, coupled to the NAND flash memory device, to apply one of a first trim profile or a second trim profile to the NAND flash memory device based at least partially on a comparison of a threshold temperature value and a sensed temperature of the NAND flash memory device.

24. The system of claim 23, further comprising a temperature sensor, thermally proximate to the NAND flash memory device, to detect the sensed temperature.

25. The system of claim 23, wherein the NAND flash memory device is to be programmed based at least partially on one or more Multi Level Cell (MLC) voltage levels.
